(19) United States
(12) Patent Application Publication
(10) Pub. No.: US 2025/0129993 A1
(43) Pub. Date: Apr. 24, 2025

(54) Tube-In-Tube Heat Pipe

(71) Applicant: Kelvin Thermal Technologies, Inc., Lafayette, CO (US)

(72) Inventors: Ryan Lewis, Boulder, CO (US); Daniel Katzman, Lafayette, CO (US); Greg Cheng, Lafayette, CO (US); Yung-Cheng Lee, Lafayette, CO (US)

(21) Appl. No.: 18/651,657

(22) Filed: Apr. 30, 2024

Related U.S. Application Data
(60) Provisional application No. 63/505,620, filed on Jun. 1, 2023.

(51) Int. Cl. F28D 15/04

(52) U.S. Cl. CPC F28D 15/046

(57) ABSTRACT

A tube-in-tube heat pipe is disclosed. A tube-in-tube heat pipe can include an outer tube having a cylindrical shape that extends from a first end to a second end and having an outer tube chamber. The outer tube can be sealed at the first and the second end. The tube-in-tube heat pipe can also include an inner tube having a cylindrical shape and disposed within the outer tube. The inner tube comprising a porous material surrounding an inner volume. The inner tube is disposed within the outer tube chamber.

### BACKGROUND

With a realization of higher integration and higher performance of electronic devices thermal management has become more and more important. New mobile technologies, in part, because of the small size and high-performance requirements, have particularly challenging thermal management scenarios.

### SUMMARY

Various tube-in-tube heat pipes are disclosed. One tube-in-tube heat pipe, for example, includes an outer tube having a cylindrical shape that extends from a first end to a second end, the outer tube having a hollow interior, the outer tube sealed at the first end and at the second end; and an inner tube having a cylindrical shape that extends from a first end and to a second end, the inner tube disposed within the hollow interior of the outer tube, the inner tube comprising a porous material surrounding an inner volume, the inner volume of the inner tube is charged with liquid, the porous material prevents vapor from penetrating into the inner volume and substantially blocking liquid flow.

Any of the tube-in-tube heat pipes disclosed in this document may include an inner tube and/or an outer tube that comprises a porous inorganic material. The porous inorganic material, for example, may include porous glass, porous copper, or porous ceramic. The porous inorganic material, for example, may be formed by dealloying the inorganic material and/or sintering micro/nanoparticles into the inorganic material.

Any of the tube-in-tube heat pipes disclosed in this document may include, for example, an inner tube that comprises organic material coated with an inorganic material.

Any of the tube-in-tube heat pipes disclosed in this document may include, for example, an inner tube may include a first asynchronous layer of mesh, and/or a second asynchronous layer of mesh that is disposed within the first asynchronous layer of mesh.

Any of the tube-in-tube heat pipes disclosed in this document may include, for example, a gap between the first asynchronous layer and an inner surface of the outer tube has an average gap width that is less than about 0.08 mm. The first asynchronous layer, for example, may enclose a core tube, and the gap between this asynchronous layer and an outer surface of the core tube has an average gap width that is less than about 0.08 mm. The first asynchronous layer, for example, may comprise a first plurality of wires and the second asynchronous layer comprises a second plurality of wires, wherein the first plurality of wires of the first asynchronous layer of mesh has a cross-sectional dimension that is half the cross-sectional dimension of the second plurality of wires of the second asynchronous layer of mesh. Either or both the first asynchronous layer or the second asynchronous layer, for example, may include a portion along the length of the inner tube that includes microparticles or nanoparticles.

Any of the tube-in-tube heat pipes disclosed in this document may include, for example, an inner tube that includes a porous polymer formed by dissolving a copolymer, track etching, or spin-casing.

A tube-in-tube heat pipe is disclosed that includes an outer tube having a cylindrical shape that extends from a first end to a second end, the outer tube having a hollow interior, the outer tube sealed at the first end and at the second end; and an inner tube having a cylindrical shape that extends from a first end and to a second end, the inner tube disposed within the hollow interior of the outer tube, the inner tube comprising a porous material surrounding an inner volume. The tube-in-tube heat pipe, for example, may be charged with a liquid. A liquid channel, for example, may be formed between the outer surface of the inner tube and the interior surface of the outer tube. A gap between the outer surface of the inner tube and the interior surface of the outer tube may, for example, prevent vapor bubbles from blocking the entire liquid flow in the liquid channel.

Any of the tube-in-tube heat pipes disclosed in this document may include, for example, an inner tube and/or an outer tube that comprises a porous inorganic material. The porous inorganic material may, for example, include a porous glass, porous copper, or porous ceramic. The porous inorganic material may, for example, be formed by dealloying the inorganic material and/or sintering micro/nanoparticles into the inorganic material.

Any of the tube-in-tube heat pipes disclosed in this document may include, for example, an inner tube that includes organic material coated with an inorganic material.

Any of the tube-in-tube heat pipes disclosed in this document may include, for example, an inner tube that includes a first asynchronous layer of mesh, and a second asynchronous layer of mesh that is disposed within the first asynchronous layer of mesh. The gap between the first asynchronous layer and an inner surface of the outer tube, for example, may have an average gap width that is less than about 0.08 mm. The first asynchronous layer, for example, encloses a core tube, and the gap between this asynchronous layer and an outer surface of the core tube has an average gap width that is less than about 0.08 mm. The first asynchronous layer, for example, may include a first plurality of wires and the second asynchronous layer comprises a second plurality of wires, wherein the first plurality of wires of the first asynchronous layer of mesh has a cross-sectional dimension that is half the cross-sectional dimension of the second plurality of wires of the second asynchronous layer of mesh. Either or both the first asynchronous layer or the second asynchronous layer may include, for example, a portion along the length of the inner tube includes microparticles or nanoparticles.

Any of the tube-in-tube heat pipes disclosed in this document may include, for example, an inner tube that comprises a porous polymer formed by dissolving a copolymer, track etching, or spin-casing.

### BRIEF DESCRIPTION OF THE FIGURES

FIG. 1A is an illustration of a vertical cross-section of an example tube-in-tube heat pipe.

FIG. 1B is an illustration of a cross-section of the tube-in-tube heat pipe shown in FIG. 1A along cross-section A-A.

FIG. 2A is an illustration of a vertical cross-section of another example tube-in-tube heat pipe.

FIG. 2B is an illustration of a cross-section of the tube-in-tube heat pipe shown in FIG. 1A along cross-section A-A.

FIG. 3A illustrate a vertical cross-section of an example layered-mesh heat pipe with a two layered mesh.

FIG. 3B is an illustration of a cross-section of the layered-mesh heat pipe shown in FIG. 3A along cross-section A-A.

FIG. 3C is an illustration of a cross-section of the layered-mesh heat pipe shown in FIG. 3A along cross-section B-B.

FIG. 3D is an illustration of a cross section of a coarse mesh.

FIG. 3E is an illustration of a cross section of a fine mesh.

FIG. 4A illustrate a vertical cross-section of an example layered-mesh heat pipe with a two layered mesh.

FIG. 4B is an illustration of a cross-section of the layered-mesh heat pipe shown in FIG. 4A along cross-section A-A.

FIG. 4C is an illustration of a cross-section of the layered-mesh heat pipe shown in FIG. 4A along cross-section B-B.

FIG. 5 illustrates an example tube-in-tube heat pipe with a wick comprising regions of different porosity.

FIG. 6 illustrates a two-dimensional structure of tube-in-tube heat pipe.

FIG. 7A is an illustration of an end view of a planar tube-in-tube heat pipe with a plurality of wicks having inner tubes.

FIG. 7B is an illustration of a top view of a planar tube-in-tube heat pipe with a plurality of wicks having inner tubes.

FIG. 8 is an illustration of a top view of a planar tube-in-tube heat pipe with a plurality of wicks with one end that converge on a localized heat source and another end coupled with a manifold wick.

FIG. 9 is an illustration of a tube-in-tube heat pipe with microwires wires within the inner tube where the inner tube is in contact with the outer tube.

FIG. 10A is an illustration of a tube-in-tube heat pipe in a compressed state.

FIG. 10B is an illustration of a tube-in-tube heat pipe in a stretched state.

### DETAILED DESCRIPTION

Various examples of tube-in-tube heat pipes are disclosed. A heat pipe includes a liquid in a porous wick and a vapor disposed within a hermetically sealed cavity. The liquid is typically in thermal equilibrium with the vapor. The cavity is often formed by a cylindrical pipe that is sealed on both ends. When heat is applied to a region of the heat pipe, it causes the liquid in the heat pipe to evaporate; the vapor is pushed through the vapor cavity to a cooler region based on the difference in saturation pressure. As it moves through the vapor cavity the vapor may carry heat by convection from the hotter region to the cooler region. The vapor condenses when it reaches the cooler region and expels heat into the environment via the cooler region. The liquid is pulled back to the hotter region by capillary forces in the wick.

A tube-in-tube heat pipe is disclosed that includes an inner tube disposed within a cylindrical pipe. The inner tube, for example, may include a porous hollow fiber, a copper tube, a glass tube, a fiber, a copper braid, or a glass braid. A fiber, for example, as used in this document, may include a braid such as a copper braid or a glass braid.

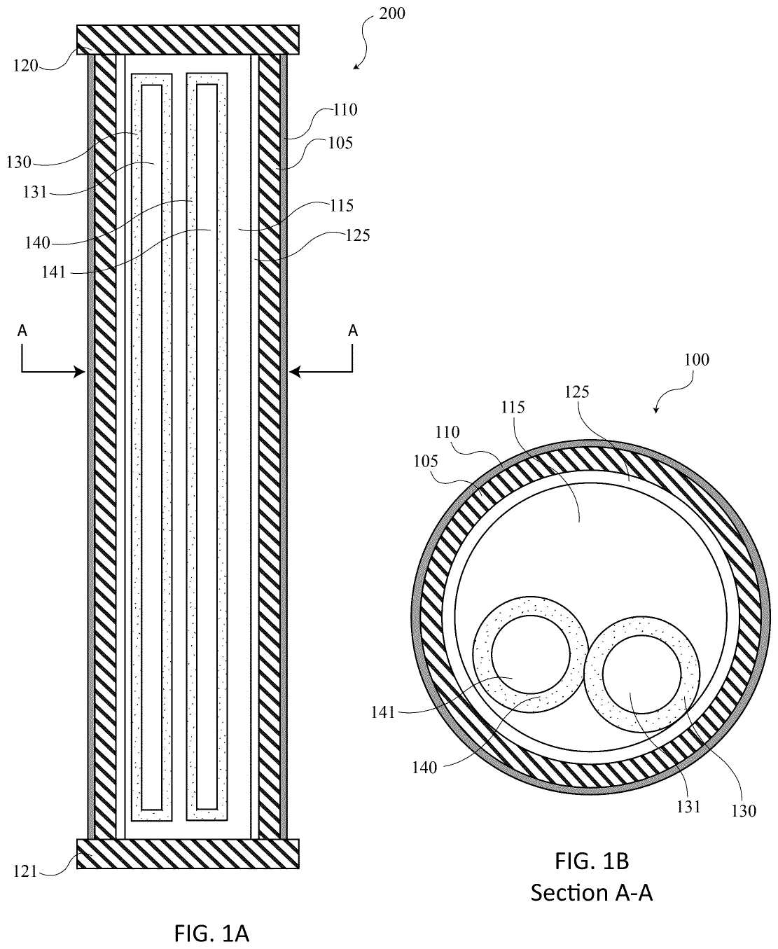

FIG. 1A is an illustration of a vertical cross-section of an example tube-in-tube heat pipe 100. FIG. 1B is an illustration of a cross-section of the tube-in-tube heat pipe 100 along cross-section A-A, which is perpendicular to the longitudinal axis of the tube-in-tube heat pipe 100.

The tube-in-tube heat pipe 100, for example, includes an outer tube 105, a first inner tube 130, and a second inner tube 140. The outer tube 105 may have a cylindrical shape and/or may be surrounded by a polymer cladding 110 that may be disposed or covered on the outer surface of the outer tube 105. The first inner tube 130 may include a first inner volume 131. The second inner tube 140 may include a second inner volume 141.

The outer tube 105 may include any type of material such as, for example, copper, aluminum, steel, stainless steel, brass, zinc, glass, etc. The outer tube 105 may be hermetically sealed on a first end 120 and a second end 121. The first end 120 and/or the second end 121 may include a cap, a crimp, a weld, a pinch-seal, a diffusion bond, solder, brazing, a weld, a glass seal, etc.

The outer tube 105 may enclose (or be charged with) a fluid within the inner volume 115 that may, for example, include water, organic solvent, acetone, any ketone, methanol, any alcohol, pentane, other hydrocarbons, etc. The fluid may also, for example, include an organic dielectric fluid such as hexane. The fluid may also, for example, include an artificial dielectric fluid such as hydrofluoroether or hydrofluoroketone, or any other artificial refrigerant.

The tube-in-tube heat pipe 100, for example, may include a passivation layer 125 on the inner wall of the outer tube 105. The passivation layer 125, for example, may prevent reactions between the material of the outer tube 105 and the internal fluid. The passivation layer 125, for example, may comprise a ceramic such as, for example, aluminum oxide, silicon oxide, silicon nitride, titanium oxide, etc. The passivation layer 125, for example, may be deposited by sol-gel, electroplating, atomic layer deposition, etc.

While two inner tubes are shown within the tube-in-tube heat pipe 100, a first inner tube 130 and a second inner tube 140, any number of inner tubes may be used. The first inner tube 130 and/or the second inner tube 140 may have a cylindrical shape.

The first inner tube 130 and/or the second inner tube 140, for example, may include a hollow tube with a first inner volume 131. Liquid may fill and/or travel through the first inner volume 131 of the first inner tube 130 and/or the second inner tube 140. The first inner volume 131 may be a liquid channel. The tubular body of the first inner tube 130 and/or the second inner tube 140, for example, may comprise a porous glass, glass braids, glass fibers, extruded glass, coarse glass mesh, fine glass mesh, etc. The tubular body of the first inner tube 130 and/or the second inner tube 140, for example, may comprise a porous copper, copper braids, copper fibers, extruded copper, coarse copper mesh, fine copper mesh, etc.

The first inner tube 130 and/or the second inner tube 140, for example, may include a cap, a crimp, a weld, a pinch-seal, a diffusion bond, solder, brazing, a weld, a glass seal, etc. on one or both ends of the first inner tube 130 and/or the second inner tube 140.

The first inner tube 130 and/or the second inner tube 140, for example, may comprise a porous material. The first inner tube 130 and/or the second inner tube 140, for example, may comprise a porous metal such as, for example, copper, aluminum, zinc, etc. The first inner tube 130 and/or the second inner tube 140, for example, may comprise a metallic tube (e.g., copper, aluminum, zinc, etc.) treated with acid to make the wall porous (e.g., dealloying). The first inner tube 130 and/or the second inner tube 140, for example, may comprise porous Kapton, Kapton that has been blasted to create pores, track etched Kapton, etc. The first inner tube 130 and/or the second inner tube 140, for example, may include a polymer or a copper coated polymer with small pores. The first inner tube 130 and/or the second inner tube 140, for example, may comprise porous copper, copper braids, copper fibers, extruded copper, coarse copper mesh, fine copper mesh, etc.

The first inner tube 130 and/or the second inner tube 140, for example, may include a plurality of pores. The plurality of pores may be formed by etching such as, for example, through a patterned mask. The plurality of pores, for example, may be formed as part of a braid, mesh, fiber, etc. The plurality of pores, for example, may be formed by dealloying or blasting. The plurality of pores, for example, may be small enough to avoid vapor penetration into the inner volume 131 of the first inner tube 130 and/or the second inner tube 140. The plurality of pores, for example, may have a pore size less than or equal to about 10,000 nm such as, for example, less than or equal to or about 100 nm, 300 nm, 1,000 nm, 3,000 nm, 7,000 nm, etc.

The first inner tube 130 and/or the second inner tube 140, for example, may have a substantially homogenous radial cross-section.

The inner diameter of the outer tube 105, for example, can be equal to or more than twice the outer diameter of the first inner tube 130 and/or the outer diameter of the second inner tube 140.

The inner diameter of the outer tube 105 can be less than or equal about 0.25, 0.5, 0.75, 0.95, 1.93, 2.90, 3.90, 4.90 mm, etc., such as, for example, less than or equal about 4.8 mm such as, for example. The outer diameter of the outer tube 105 can be less than or equal about 5.0 mm such as, for example, less than or equal to about 0.35 mm, 0.65 mm, 1.0 mm, 2.0 mm, 3.0 mm, 4.0 mm, 5 mm, etc. The inner diameter of the first inner tube 130 and/or the second inner tube 140 may be less or equal to about 0.25 mm such as, for example, less than or equal to about 0.025 mm, 0.050 mm, 0.100 mm, etc. The outer diameter of the first inner tube 130 and/or the second inner tube 140 may be less or equal to about 0.5 mm such as, for example, less than or equal to about 0.050 mm, 0.075 mm, 0.150 mm, etc.

The first inner tube 130 and/or the second inner tube 140, for example, may comprise polyethersulfone (PES) and/or modified-polyethersulfone (mPES). The PES and/or mPES may be formed through a spinning process such as, for example, a wet-spinning, dry-spinning, wet-dry jet spinning, melt spinning, etc.

The first inner tube 130 and/or the second inner tube 140, for example, may comprise a polymer such as, for example, polyimide, polyester, polycarbonate, etc. The pores in the first inner tube 130 and/or the second inner tube 140 may be formed by dissolving a copolymer, track etching, spin-casing, etc. The first inner tube 130 and/or the second inner tube 140 may include a hollow fiber tangential flow filter. A fiber tangential flow filter, for example, may be a filter developed to separate impurities from any fluids channeled through it. The first inner tube 130 and/or the second inner tube 140, for example, may be coated with a ceramic using ALD, CVD, PECVD, etc.

As another example, a tube-in-tube heat pipe 100 may include a plurality of inner tubes bundled together. Each of the plurality of inner tubes may comprise any of the examples of the first inner tube 130 described in this document. The plurality of inner tubes may or may not be bonded together. Each of the plurality of inner tubes may or may not be porous. One or more of the plurality of inner tubes, for example, may be sealed at intermediate lengths along the longitudinal length of the inner tube, which may provide paths for the liquid to flow through inner tube walls between inner tubes of the plurality of inner tubes. Each of the plurality of inner tubes, for example, may be sealed with outer porous walls within which liquid may flow.

A plurality of inner tubes bundled, for example, can be formed in the manner of optical fibers (e.g., photonic crystal fibers); for example, a preform with a tubular shape may be drawn into a micro-scale thickness while retaining the features of the preform. The fibers, for example, may be formed by spinning from an extruder with multiple nozzles.

A tube-in-tube heat pipe 100 may be partially flattened into an oval or oblong shape. This, for example, may reduce the thickness of the tube-in-tube heat pipe 100 and/or increase the flexibility of the tube-in-tube heat pipe 100. A tube-in-tube heat pipe 100 may be flattened along the entire length of the tube-in-tube heat pipe 100 or in some or many regions along the longitudinal length of the heat pipe. The flattened portions of the tube-in-tube heat pipe 100, for example, may have different thicknesses. The flattened region of a tube-in-tube heat pipe 100 may be placed near a heat source. The flattened portions may be flattened such that the inner walls of the outer tube 105 is in contact with the outer surface of the first inner tube 130.

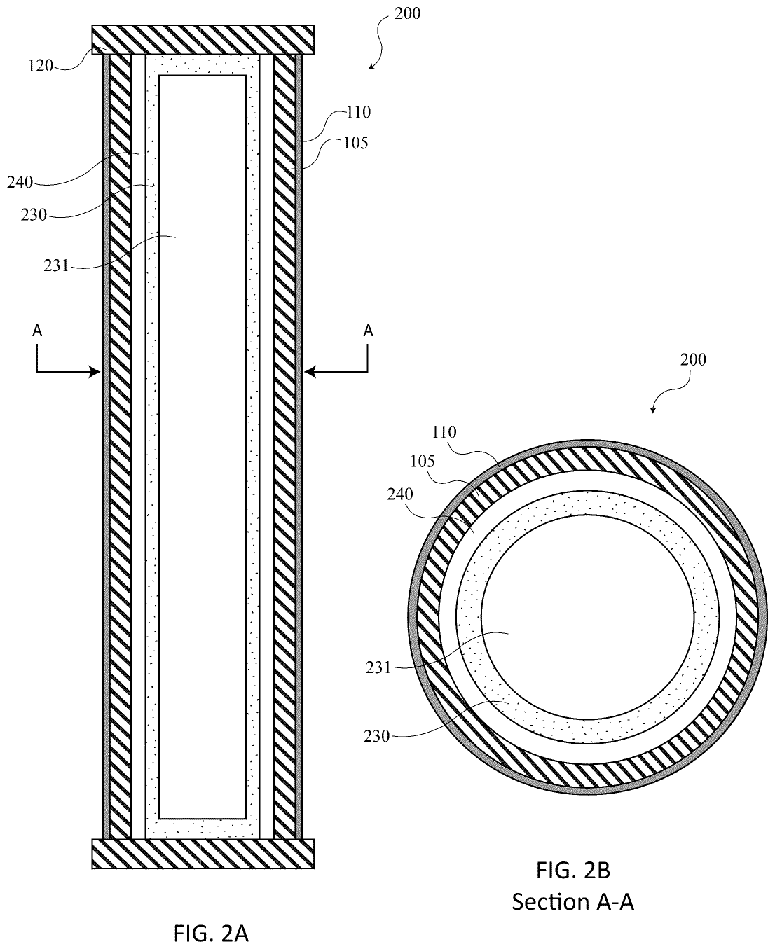

FIG. 2A is an illustration of a vertical cross-section of another example tube-in-tube heat pipe 200 with the cross-section parallel with the tube axis. FIG. 2B is an illustration of a cross-section of the tube-in-tube heat pipe 200 shown in FIG. 2A along cross-section A-A, which is perpendicular to the tube axis.

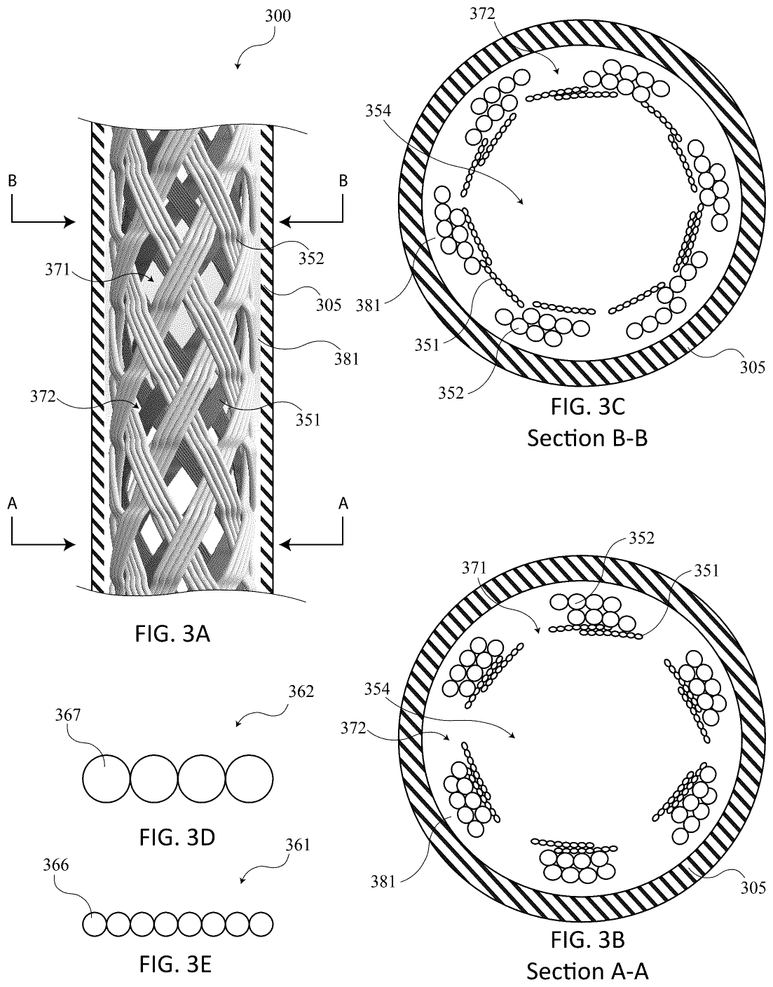

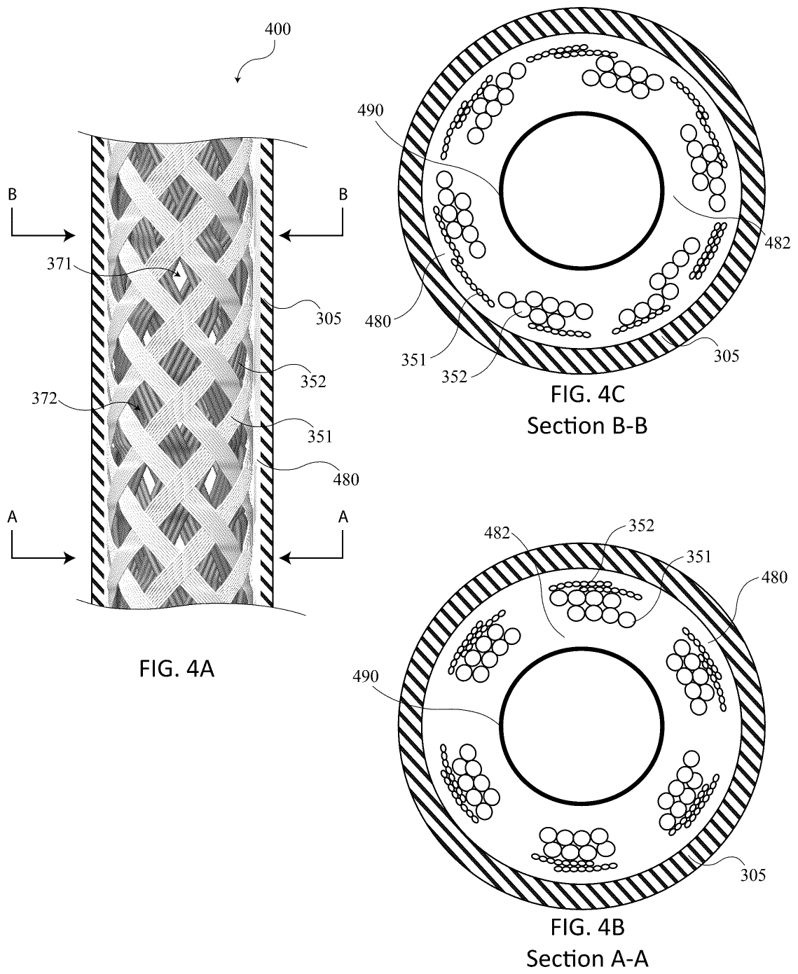

The tube-in-tube heat pipe 200, for example, may include an inner tube 230 that may or may not be connected to the inner wall of outer tube 105. Vapor may be transport through the inner volume 231 of the inner tube 230. Liquid may be transported in the space 240 between the outer tube 105 and the inner tube 230. The inner tube 230, for example, may include a mesh. The inner tube 230, for example, may comprise a tube of braided material such as, for example, one or both of fine mesh 351 and coarse mesh 352 shown in FIG. 3A and FIG. 4A.

FIG. 3A illustrate a vertical cross-section of an example tube-in-tube heat pipe 300 that includes a coarse mesh 352 and a fine mesh 351 layered within an outer tube 305. FIG. 3B is an illustration of a cross-section of the tube-in-tube heat pipe 300 shown in FIG. 3A along cross-section A-A. FIG. 3C is an illustration of a cross-section of the tube-in-tube heat pipe 300 shown in FIG. 3A along cross-section B-B.

A tube-in-tube heat pipe 300, for example, may include two asynchronous mesh layers: a coarse mesh 352 (or first asynchronous layer) and a fine mesh 351 (or second asynchronous layer). The strands of the coarse mesh 352 and/or the strands of the fine mesh 351 may be asynchronous relative to each other such as, for example, such that pores or openings in the coarse mesh 352 do not align with the pores or openings in the fine mesh 351. While two layers of mesh are shown, any number of layers of mesh may be used.

The coarse mesh 352 may be formed and/or woven in the shape of a tube. The fine mesh 351 may also be formed and/or woven in the shape of a tube. The coarse mesh 352 may be disposed and/or covered over the exterior of the fine mesh 351 (or vice versa) to create a two layered mesh. The two layered mesh (e.g., with a layer of fine mesh 351 and a layer of coarse mesh 352) may be disposed within outer tube 305. For example, a first layer of mesh may cover a second layer of mesh.

The outer tube 305 may comprise any of the examples of the outer tube 105 described in this document. The outer tube 305 may be crimped or sealed on both ends.

FIG. 3E is an illustration of a cross section of an example fine strand 361 that can be woven together to make a fine mesh 351. A fine strand 361 may include a ribbon of independent fine wires 366 or an extruded group of plurality of fine wires 366.

A fine strand 361, for example, may include a plurality of fine wires 366 such as, for example, 1-12 fine wires 366 per fine strand 361. Each fine wire 366, for example, can have a diameter from 0.001 to 0.1 mm or larger such as, for example, less than about 0.03 mm.

Each of fine strands 361, for example, may comprise glass, copper, or other inorganic or organic materials.

A fine mesh 351, for example, may be woven into a mesh of fine strands 361.

The fine mesh 351, for example, may have a mesh number from #5, #10, #15, #20, #25, #30 or higher for pitches of 5.08 mm, 2.54 mm, 1.69 mm, 1.27 mm, 1.02 mm, 0.85 mm, respectively. Where mush number is the number of openings per inch. And the pitch is the distance between the midpoints of two adjacent openings in the mesh. In some examples, the diameter of fine wire 366 and the mesh number of the fine mesh 351 are two considerations during the design for a tube-in-tube heat pipe. For example, a small wire diameter and a large mesh number may be used. This may be done, for example, to form smaller pore sizes that may be good for higher capillary pressure.

FIG. 3D is an illustration of a cross section of an example coarse strand 362 that can be woven together to make a coarse mesh 352. A coarse strand 362 may include a ribbon of independent coarse wires 367 or an extruded group of plurality of coarse wires 367.

A coarse strand 362, for example, may include a plurality of coarse wires 367 such as, for example, 1-12 coarse wires 367 per coarse strand 362. Each coarse wire 367, for example, can have a diameter from 0.001 to 0.1 mm or larger such as, for example, less than about 0.08 mm. Each coarse wire 367 of a coarse strand 362, for example, has a diameter that is smaller than the diameter of a coarse wire 367 of a coarse mesh 352. Each coarse wire 367 of a coarse mesh 352 may have a cross section dimension (e.g., diameter) that is about twice a cross section dimension of a wire 367 of a fine mesh 351.

Each coarse strand 362, for example, may comprise glass, copper, or other inorganic or organic materials. A coarse mesh 352, for example, may be woven from one or more coarse strands 362.

The coarse mesh 352, for example, may have a mesh number from #5, #10, #15, #20, #25, #30 or higher for pitches of 5.08 mm, 2.54 mm, 1.69 mm, 1.27 mm, 1.02 mm, 0.85 mm, respectively. Where mush number is the number of openings per inch. And the pitch is the distance between the midpoints of two adjacent openings in the mesh. In some examples, the diameter of coarse wire 367 and the mesh number of the coarse mesh 352 are two considerations during the design for a tube-in-tube heat pipe. For example, a small wire diameter and a large mesh number may be used. This may be done, for example, to form smaller pore sizes that may be good for higher capillary pressure.

In one example, the coarse mesh 352 may have a mesh number of 25, and the fine mesh 351 may have a mesh number of 15.

The fine mesh 351 may be formed (or woven) into a tube shape with a plurality of diamond-shaped openings 371 formed between weaves of the fine mesh 351. The coarse mesh 352 may be formed (or woven) into a tube shape with a plurality of diamond-shaped openings 372 formed between weaves of the coarse mesh 352. In some areas, the openings 371 in the fine mesh 351 and the openings 372 in the coarse mesh 352 may line up, and in other places the openings may not line up. The location of these openings in the mesh may be random and the alignment between the fine mesh 351 and the coarse mesh 352 may not be aligned during manufacturing. The size and the number of the openings 371 and openings 372 may depend on the mesh number.

The fine mesh 351, for example, may separate vapor and liquid transport channels. The coarse mesh 352 and the gap between the coarse mesh 352 and the outer tube 305, for example, may form a liquid transport channel. Some of the openings 371 in the fine mesh 351 may be partially blocked by the strands of the of the coarse mesh 352 or the openings in the fine mesh 351 may or may not be aligned with the openings in the coarse mesh 352. If an opening 371 is substantially blocked (or e.g., unaligned), a vapor-liquid interface may be maintained by surface tension with the radius of the interface related to the pressure difference between vapor and liquid.

If an opening 371 is not substantially blocked (or e.g., aligned), a separate vapor and liquid transport channels may not be formed. For example, vapor may pass through openings 371 from the vapor channel 354 into the gap 381, and/or bubbles may form in the liquid transport. Any such bubbles, for example, could block part of the liquid transport channel within gap 381. Yet, the gap 381 between the coarse mesh 352 and the interior wall of the outer tube 305 may constrain the size of the bubbles and mitigate problems with bubbles blocking the liquid transport channel in the gap 381. The gap 381, for example, may be large enough for an effective liquid flow and small enough to restrict bubble growth outside the opening 372 of the coarse mesh 352.

Because each coarse strand 362 of each coarse mesh 352 is not flat, the gap 381 may vary along the length of portions of the inner wall of the outer tube 305. The gap 381 may be defined by the diameter of the coarse wires 367 of each coarse strand 362 and the interior wall of the outer tube 305. As such, the width of the gap 381 may vary along the length of a coarse strand 362 and/or along the length of a coarse mesh 352. For example, the average width of the gap 381 may be smaller than the diameter of a coarse wire 367. The gap 381 along substantially the length of a coarse strand 362 and/or along the length of a coarse mesh 352 may have an average width from 0.0 mm to 0.08 mm.

In some examples, the resistance of the liquid flow within the gap 381 may increase as the width of the gap 381 is reduced and the resistance of the liquid flow within the gap 381 may decrease as the width of the gap 381 is increased. In such examples, the likelihood of bubbles penetrating into other diamond openings increases with as the width of the gap 381 is increased and reduced as the width of the gap 381 is decreased. The diameter of a coarse wire 367, which effects the width of the gap 381, may be important to consider in the tube-in-tube design along with many other factors.

FIG. 4A illustrates a vertical cross-section of an example layered-mesh heat pipe 400 with a two layered mesh. FIG. 4B is an illustration of a cross-section of the layered-mesh heat pipe 400 shown in FIG. 4A along cross-section A-A. FIG. 4C is an illustration of a cross-section of the layered-mesh heat pipe 400 shown in FIG. 4A along cross-section B-B.

In this example, the coarse mesh 352 is on the inside of the fine mesh 351. An inner tube 490 may be included within the coarse mesh 352 and the fine mesh 351. An inner gap 482 may exist between the coarse mesh 352 and the outer wall of the inner tube 490. An outer gap 480 may exist between the fine mesh 351 and the inner wall of the outer tube 305. The inner gap 482 may be the liquid channel and the outer gap 480 may be the vapor channel with the two layered mesh (e.g., fine mesh 351 and coarse mesh 352) between the two channels. Liquid may flow within the inner gap 482.

The tube-in-tube heat pipe 100, the tube-in-tube heat pipe 200, and/or the tube-in-tube heat pipe 300 can be substantially RF transparent. For example, the outer tube 105 (or outer tube 305) may comprise glass that may be coated with a polymer. The polymer, for example, may improve the flexibility and/or robustness of the glass. Any of the inner tubes (e.g., first inner tube 130, second inner tube 140, inner tube 230, inner tube 490, fine mesh 351, and/or coarse mesh 352 may comprise porous glass, porous ceramic, dielectric, or other inorganic materials. Thermal vias, for example, may pass through any of the inner tubes. This may, for example, reduce evaporator thermal resistance. Any of the first inner tubes, for example, may include porous glass or porous ceramic that is formed by dealloying glass or ceramic and/or sintering micro/nanoparticles into the glass or ceramic.

Any of the first inner tubes, for example, may be bonded to the inside of an outer tube. For example, bonding particles may be disposed between the inside of the outer tube and the outside of the inner tube. The bonding particles, for example, may comprise glass (e.g., scaled glass), silver, or other metal particles. The bonding particles, for example, may have a melting and/or sintering temperature below 250° C. This temperature, for example, may be much lower than the melting temperature (961.8° C.) of silver. The melting temperature and/or sintering temperature can be reduced substantially when the diameters of the particles are decreased.

In this example, the outer tube 105 may comprise glass and may be sealed by local fusion bonding such as, for example, by a laser, heat press, arc-discharge weld, or other welding or sealing method. The outer tube 105, for example, may be sealed by frit bonding, glass-compatible soldering or welding, or epoxy followed by a hermetic seal onto the epoxy.

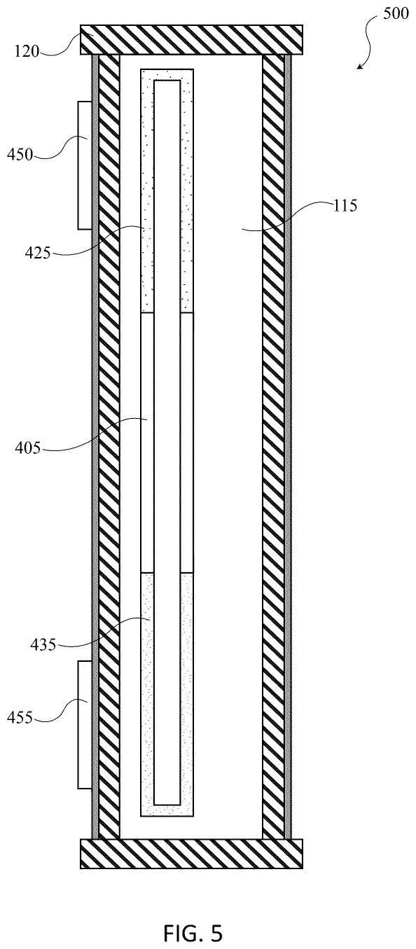

An inner tube (e.g., first inner tube 130, second inner tube 140, inner tube 230, inner tube 490, etc.) may have a variable porosity along the length of the tube. FIG. 5 illustrates an example tube-in-tube heat pipe 500 with an inner tube having different porous regions: a region with no pores 405, a region with nanopores 425 (nanometer sized pores: e.g., 100 nm, 250 nm, 500 nm, 750 nm, etc.), and a region with micropores 435 (micron sized pores: e.g., 1 micron, 10 micron, 25 micron, 50 micron, 100 micron, etc.). The region with nanopores 425 and/or the region with micropores 435, for example, may be treated to create the pores within the inner tube.

Any number of regions may be included with different levels of porosity. The tube-in-tube heat pipe 500 may be arranged, for example, in use so that the region with micropores 435 is the condenser and is placed near a cool area 455 and the region with nanopores 425 is the evaporator and is placed near a heat source 450. The areas where there is no evaporation or condensation may be regions of the inner tube with no pores 405. As another example, the region with micropores 435 can be the evaporator while the rest of region may comprise a region with no pores 405. As another example, the region with nanopores 425 can be the evaporator while the rest of the inner tube may be a region with no pores 405.

As another example, copper microparticles or copper nanoparticles can be bonded (e.g., via sintering) to a copper mesh (e.g., as part of an inner tube) such as, for example, a copper mesh comprising a two layered mesh comprising a fine mesh 351 and a coarse mesh 352. These copper microparticles or copper nanoparticles, for example, can be used to bond the copper mesh to an outer tube.

As another example, glass microparticles or glass nanoparticles can be bonded to a glass mesh such as, for example, a glass mesh (e.g., as part of an inner tube) comprising a two layered mesh comprising a fine mesh 351 and a coarse mesh 352. These glass microparticles or glass nanoparticles, for example, can be used to bond the glass mesh to an outer tube.

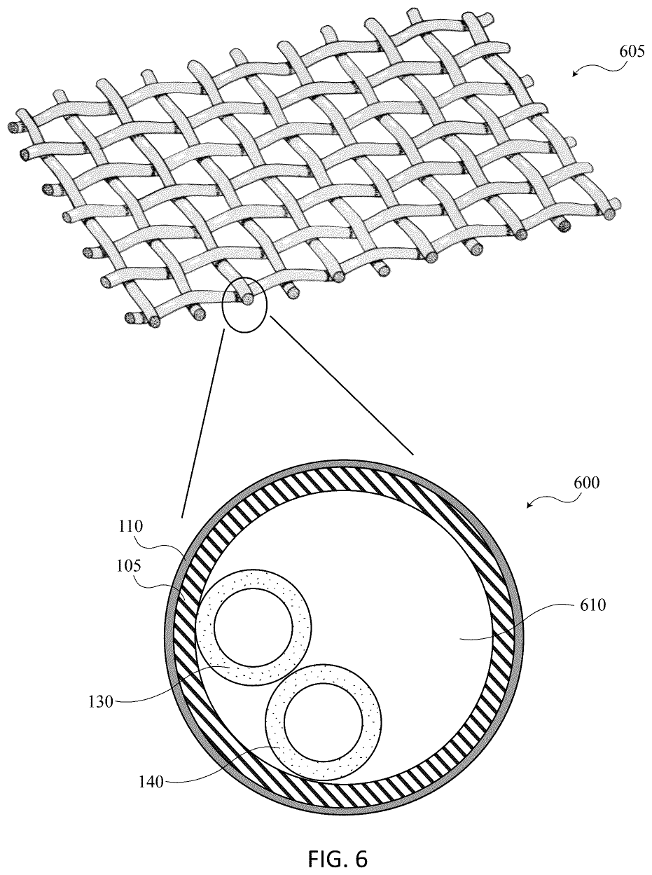

FIG. 6 illustrates a cross-section of a tube-in-tube heat pipe 600. One or both of the first inner tube 130 and/or the second inner tube 140 may include a woven mesh 605. Individual tube-in-tube heat pipes may be shorter than a length of the two-dimensional structure. The spaces 610 between heat pipes, for example, can be filled with a polymer, glass fiber, metal, etc., which may improve thermal conductivity.

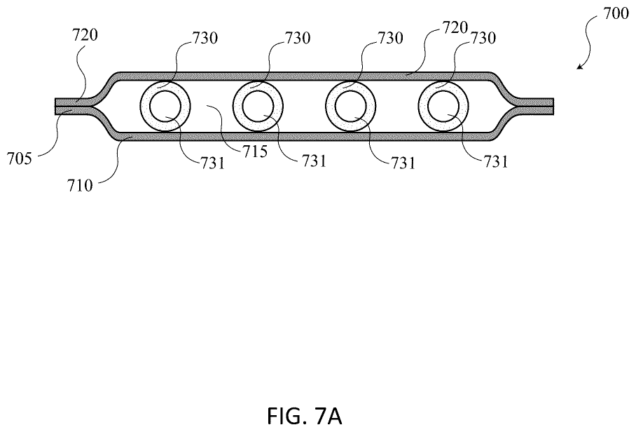

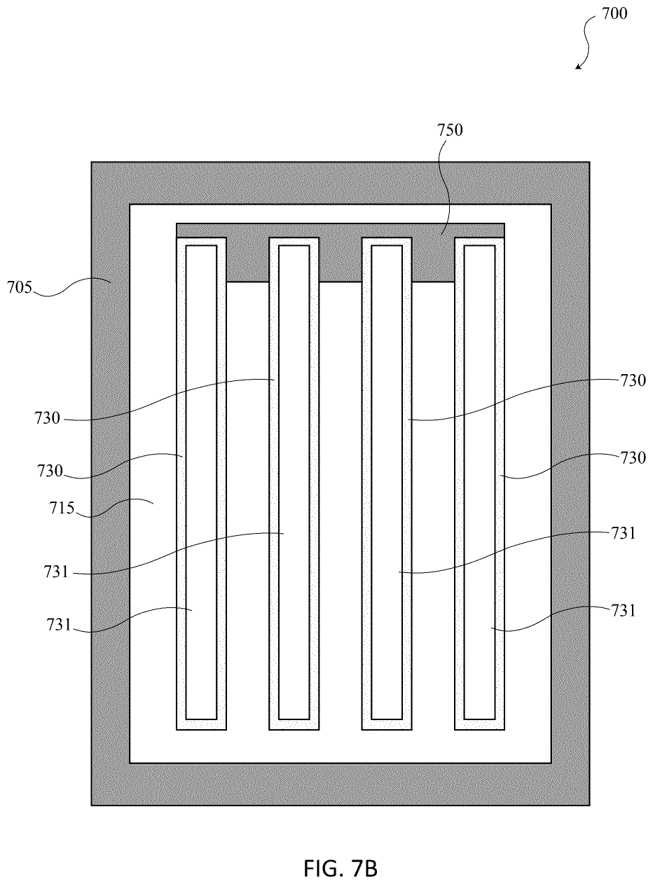

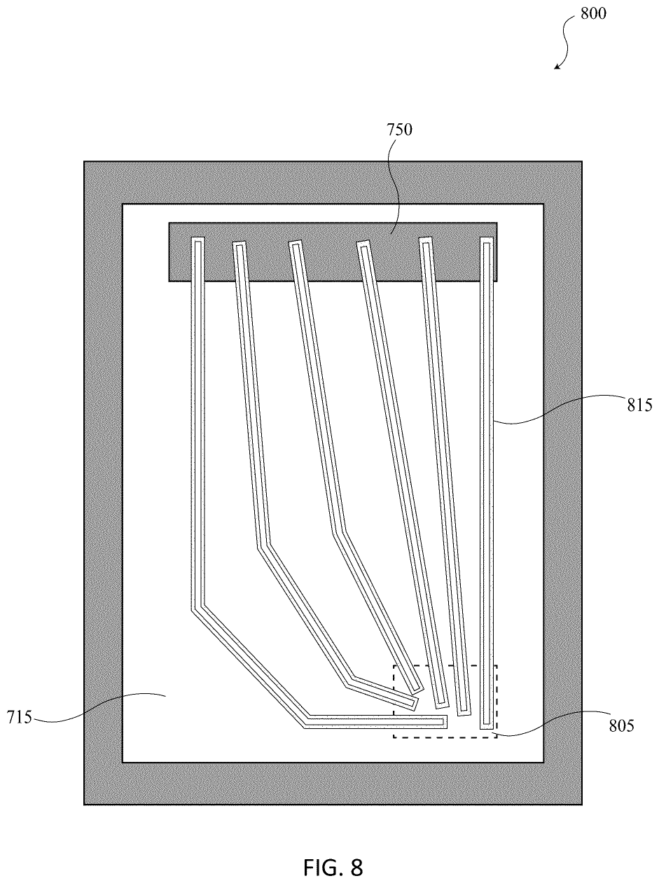

FIG. 7A is an illustration of an end view and FIG. 7B is an illustration of a top view of a planar tube-in-tube heat pipe 700 with a plurality of inner tubes 730. In this example, a top casing 720 and a bottom casing 710 may be planar layers that are sealed together around the periphery of the casings 705. A plurality of inner tubes 730 having inner volumes 731 may be disposed within the two casings. In this example, the width (e.g., 1 cm, 3 cm, 5 cm, etc.) of the planar tube-in-tube heat pipe 700 is substantially greater than the thickness (e.g., 0.075 mm, 0.1 mm, 0.2 mm, 0.5 mm etc.).

The inner chamber 715 may include any fluid such as, for example, water, organic solvent, acetone, any ketone, methanol, any alcohol, pentane, other hydrocarbons, etc.

Each of the plurality of inner tubes 730 may be a first inner tube 130 or include any of the components disclosed in this document describing a first inner tube 130. Each of the plurality of inner tubes 730 may include an inner volume 731.

The plurality of inner tubes 730 may be coupled with a wick manifold 750 that is disposed between the bottom casing 710 and the top casing 720. The wick manifold 750, for example, may be coupled to an end of each of the plurality of inner tubes 730. The wick manifold 750, for example, may comprise a mesh, a sintered particle wick, micropillars, etc. The wick manifold 750 may be placed near a cooling region of an electronic device.

The wick manifold 750, for example, may include a hollow region, which may be coupled with the inner volume 731 of each of the plurality of inner tubes 730, which may allow for the liquid to flow from the inner volumes 731 into the hollow region of the wick manifold 750 and vice versa. As another example, the inner volumes 731 of each of the plurality of inner tubes 730 may be isolated from a hollow region of the manifold. Liquid, for example, may flow from the inner volumes 731 through the porous walls of the inner tubes 730 into the hollow region of the wick manifold.

FIG. 8 is an illustration of a top view of a planar tube-in-tube heat pipe 800 with a plurality of inner tubes 815, each of the plurality of inner tubes 815 having inner volumes. The plurality of inner tubes 815 may comprise any of the features of the first inner tube 130, the second inner tube 140, the inner tube 230, and/or the inner tube 490, etc. Each of the plurality of inner tubes 815 has a first end that converge on a heat source 805 and a second end coupled with a wick manifold 750 as described above with FIG. 7B. The wick manifold 750 may be curved or bent to bring the liquid from the wick manifold 750 to the heat source 805.

The inner chamber 715 may include any fluid such as, for example, water, organic solvent, acetone, any ketone, methanol, any alcohol, pentane, other hydrocarbons, etc.

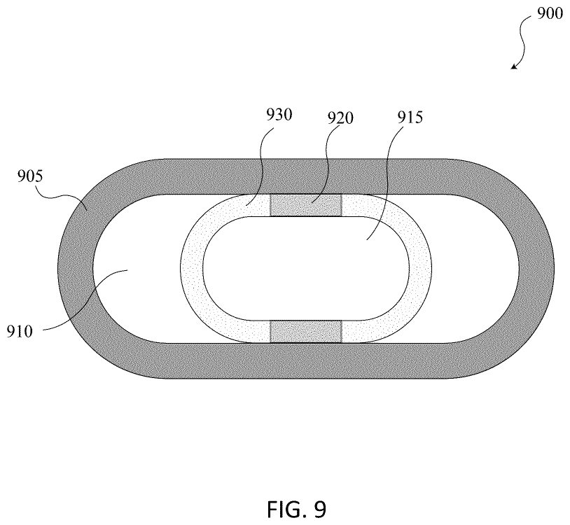

FIG. 9 is an illustration of a tube-in-tube heat pipe 900 with an inner tube 930 having microwires 920. The inner tube 930 may be in contact with the outer tube 905. In this example, vapor may be located within the inner volume 915 of the inner tube 930 and liquid may be located within the inner volume 910 of the outer tube 905. The outer tube 905, for example, may comprise an electrical conductor. The inner tube 930, for example, may comprise a material with a low thermal conductivity such as, for example, glass or ceramic. The inner tube 930 may include any or all portions of the first inner tube 130 as described in this document.

The microwires 920, for example, may be electroplated and/or may extend into the inner tube 930. The microwires 920 may comprise copper or another metal that is disposed within the pores of the inner tube 930. The microwires 920 may form thermal vias between the outer tube 905 and the inner tube 930 allowing heat to transfer from the outer tube 905 into the inner tube 930. The microwires 920, for example, may also extend into the outer tube 905.

A planar vapor chamber may include a wick having a first array of inner tubes and a second array of inner tubes. The first array, for example, may include a first array having a plurality of inner tubes running substantially parallel to each other. The second array, for example, may include a plurality of porous tubes running perpendicular to the first array. Each inner tube of the first array of inner tubes may include any of the inner tubes as disclosed in this document (e.g., the first inner tube 130). In this example, liquid can be transferred from one inner tubes to any of the other inner tubes.

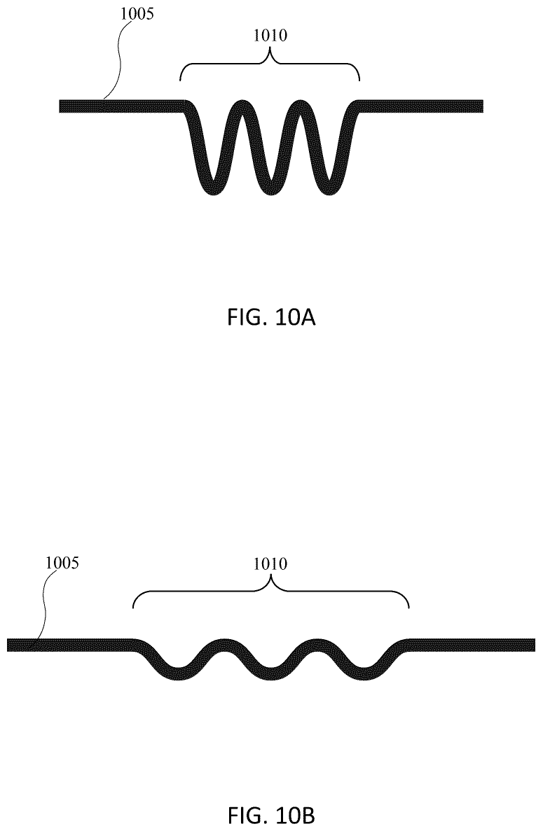

Any of the tube-in-tube heat pipes described in this document may have one or more bends to improve flexibility by translating flexing action into torsional action. FIG. 10A shows a portion of a heat pipe 1005 with a bend 1010 in a compressed configuration and FIG. 10B shows a portion of the heat pipe 1005 with bend 1010 in a stretched configuration. The tube-in-tube heat pipe can be bent in one or multiple locations to form a laterally stretchable or compressible heat pipe to form of a planar spring.

Unless otherwise specified, the term “substantially” means within 5% or 10% of the value referred to or within manufacturing tolerances. Unless otherwise specified, the term “about” means within 5% or 10% of the value referred to or within manufacturing tolerances.

The conjunction “or” is inclusive.

The terms “first”, “second”, “third”, etc. are used to distinguish respective elements and are not used to denote a particular order of those elements unless otherwise specified or order is explicitly described or required.

Numerous specific details are set forth to provide a thorough understanding of the claimed subject matter. However, those skilled in the art will understand that the claimed subject matter may be practiced without these specific details. In other instances, methods, apparatuses or systems that would be known by one of ordinary skill have not been described in detail so as not to obscure claimed subject matter.

While the present subject matter has been described in detail with respect to specific examples thereof, it will be appreciated that those skilled in the art, upon attaining an understanding of the foregoing, may readily produce alterations to, variations of, and equivalents to such examples. Accordingly, the present disclosure has been presented for purposes of example rather than limitation, and does not preclude inclusion of such modifications, variations and/or additions to the present subject matter as would be readily apparent to one of ordinary skill in the art.

1. A tube-in-tube heat pipe comprising:
an outer tube having a cylindrical shape that extends from a first end to a second end, the outer tube having a hollow interior, the outer tube sealed at the first end and at the second end; and
an inner tube having a cylindrical shape that extends from a first end and to a second end, the inner tube disposed within the hollow interior of the outer tube, the inner tube comprising a porous material surrounding an inner volume, the inner volume of the inner tube is charged with liquid, the porous material prevents vapor from penetrating into the inner volume and substantially blocking liquid flow.

2. The tube-in-tube heat pipe according to claim 1, wherein the inner tube and/or the outer tube comprises a porous inorganic material.

1. The tube-in-tube heat pipe according to claim 2, wherein porous inorganic material comprises porous glass, porous copper, or porous ceramic.

2. The tube-in-tube heat pipe according to claim 2, wherein the porous inorganic material is formed by dealloying the inorganic material and/or sintering micro/nanoparticles into the inorganic material.

3. The tube-in-tube heat pipe according to claim 1, wherein the inner tube comprises organic material coated with an inorganic material.

6. The tube-in-tube heat pipe according to claim 1, wherein the inner tube comprises a first asynchronous layer of mesh, and a second asynchronous layer of mesh that is disposed within the first asynchronous layer of mesh.

4. The tube-in-tube heat pipe according to claim 6, wherein a gap between the first asynchronous layer and an inner surface of the outer tube has an average gap width that is less than about 0.08 mm.

5. The tube-in-tube heat pipe according to claim 6, wherein the first asynchronous layer encloses a core tube, and the gap between this asynchronous layer and an outer surface of the core tube has an average gap width that is less than about 0.08 mm.

6. The tube-in-tube heat pipe according to claim 6, wherein the first asynchronous layer comprises a first plurality of wires and the second asynchronous layer comprises a second plurality of wires, wherein the first plurality of wires of the first asynchronous layer of mesh has a cross-sectional dimension that is half the cross-sectional dimension of the second plurality of wires of the second asynchronous layer of mesh.

7. The tube-in-tube heat pipe according to claim 6, wherein either or both the first asynchronous layer or the second asynchronous layer includes a portion along the length of the inner tube that includes microparticles or nanoparticles.

8. The tube-in-tube heat pipe according to claim 1, wherein the inner tube comprises a porous polymer formed by dissolving a copolymer, track etching, or spin-casing.

12. A tube-in-tube heat pipe comprising:
an outer tube having a cylindrical shape that extends from a first end to a second end, the outer tube having a hollow interior, the outer tube sealed at the first end and at the second end; and
an inner tube having a cylindrical shape that extends from a first end and to a second end, the inner tube disposed within the hollow interior of the outer tube, the inner tube comprising a porous material surrounding an inner volume; wherein:
the tube-in-tube heat pipe is charged with a liquid;
a liquid channel is formed between the outer surface of the inner tube and the interior surface of the outer tube; and
a gap between the outer surface of the inner tube and the interior surface of the outer tube that prevents vapor bubbles from blocking the entire liquid flow in the liquid channel.

13. The tube-in-tube heat pipe according to claim 12, wherein the inner tube and/or the outer tube comprises a porous inorganic material.

9. The tube-in-tube heat pipe according to claim 13, wherein porous inorganic material comprises porous glass, porous copper, or porous ceramic.

10. The tube-in-tube heat pipe according to claim 13, wherein the porous inorganic material is formed by dealloying the inorganic material and/or sintering micro/nanoparticles into the inorganic material.

11. The tube-in-tube heat pipe according to claim 12, wherein the inner tube comprises organic material coated with an inorganic material.

17. The tube-in-tube heat pipe according to claim 12, wherein the inner tube comprises a first asynchronous layer of mesh, and a second asynchronous layer of mesh that is disposed within the first asynchronous layer of mesh.

12. The tube-in-tube heat pipe according to claim 17, wherein a gap between the first asynchronous layer and an inner surface of the outer tube has an average gap width that is less than about 0.08 mm.

13. The tube-in-tube heat pipe according to claim 17, wherein the first asynchronous layer encloses a core tube, and the gap between this asynchronous layer and an outer surface of the core tube has an average gap width that is less than about 0.08 mm.

14. The tube-in-tube heat pipe according to claim 17, wherein the first asynchronous layer comprises a first plurality of wires and the second asynchronous layer comprises a second plurality of wires, wherein the first plurality of wires of the first asynchronous layer of mesh has a cross-sectional dimension that is half the cross-sectional dimension of the second plurality of wires of the second asynchronous layer of mesh.

15. The tube-in-tube heat pipe according to claim 17, wherein either or both the first asynchronous layer or the second asynchronous layer includes a portion along the length of the inner tube includes microparticles or nanoparticles.

16. The tube-in-tube heat pipe according to claim 12, wherein the inner tube comprises a porous polymer formed by dissolving a copolymer, track etching, or spin-casing.
